(19) United States
(12) Patent Application Publication
(10) Pub. No.: US 2026/0255527 A1
(43) Pub. Date: Aug. 27, 2026

(54) POWER SUPPLY AND BRACKET FOR REINFORCING STRUCTURE OF BACKPLATE THEREOF

(71) Applicant: ACBEL POLYTECH INC., New Taipei City (TW)

(72) Inventors: Cheng-Chia LIN, New Taipei City (TW); Yueh-Feng LI, New Taipei City (TW); Nung-Chin KAO, New Taipei City (TW); Chia-Hung CHIEN, New Taipei City (TW)

(73) Assignee: ACBEL POLYTECH INC., New Taipei City (TW)

(21) Appl. No.: 19/540,091

(22) Filed: Feb. 13, 2026

(30) Foreign Application Priority Data
Feb. 24, 2025 (TW) 114106708

(51) Int. Cl. H05K 7/20; G06F 1/18; G06F 1/183; G06F 1/187; G06F 1/188; H05K 7/14

(52) U.S. Cl. CPC H05K 7/20172; G06F 1/181; G06F 1/183; G06F 1/187; G06F 1/188; H05K 7/1492

(57) ABSTRACT

A bracket for reinforcing a structure of a backplate is configured to fix a modular back panel and has a fixing section covering one of plate sides of the modular back panel, an upper connecting section extending and bending from an end of the fixing section, and a lower connecting section. The lower connecting section bends from another end of the fixing section. A power supply has a top panel, a side panel, a bottom panel, an installation panel, and a main panel mounted on the bottom panel. The modular back panel is inserted on the main panel. The bracket is sleeved on the plate side. The upper connecting section is fixed on the top panel. The lower connecting section is disposed through and secured to the main panel. Therefore, the modular back panel can be stably located on the installation panel and the main panel.

### BACKGROUND OF THE INVENTION

### 1. Field of the Invention

The present invention relates to a power supply and a bracket, especially to a power supply and a bracket for reinforcing a structure of a backplate thereof.

### 2. Description of the Prior Arts

With reference to FIGS. 10 and FIG. 11, taking a conventional power supply as an example, a main panel 90 and a modular back panel 91 are mounted in a casing of the conventional power supply. Multiple sockets 92 are disposed on the modular back panel 91, and an end of the modular back panel 91 is inserted into the main panel 90. Therefore, when connectors are plugged into or unplugged from the sockets 92 of the modular back panel 91, the modular back panel 91 needs to withstand larger pulling and pushing forces. Insufficient structural stability will lead to solder cracking at the connection between the modular back panel 91 and the main panel 90, or damage electronic components due to forced bending of the modular back panel 91. Therefore, to prevent the aforementioned situation, currently studs are often installed on the casing, and the modular back panel 91 is locked to the studs to support the modular back panel 91.

However, as products are trending towards thinner and smaller designs, the size of the casing has been significantly reduced, and the internal space of the casing is also very limited. There is no extra space to install additional studs to support the modular back panel 91.

The overall structure of the conventional power supply has the aforementioned problems and shortcomings, and thus needs to be improved.

### SUMMARY OF THE INVENTION

The main objective of the present invention is to provide a power supply and a bracket for reinforcing a structure of a backplate thereof. The bracket for reinforcing the structure is used to be sleeved on a modular back panel and fixed on a casing and a main panel, thereby enhancing the stability of the modular back panel.

The bracket for reinforcing the structure of the backplate is configured to fix a modular back panel. The modular back panel comprises two opposite plate surfaces in front and back and two opposite plate sides on left and right.

The bracket for reinforcing the structure of the backplate comprises a fixing section, an upper connecting section, and a lower connecting section. The fixing section is configured to cover one of the plate sides of the modular back panel. The upper connecting section extends and bends from an end of the fixing section. An upper through hole is formed through the upper connecting section. The lower connecting section bends from another end of the fixing section, extends for a distance, and then extends in a direction away from the fixing section.

The power supply comprises a casing assembly, a fan module, a main panel, and the modular back panel. The casing assembly comprises a top panel, a side panel, a bottom panel, and an installation panel to form an accommodating space with at least one connecting port. The installation panel is connected to the top panel and the bottom panel. The side panel is connected to the installation panel, the top panel, and the bottom panel. The fan module is mounted in the accommodating space and comprises an outlet side toward the installation panel. The main panel is mounted on the bottom panel. The modular back panel is mounted on the main panel.

The casing assembly further comprises a bracket for reinforcing the structure of the backplate as mentioned above. The bracket for reinforcing the structure of the backplate is sleeved on one of the plate sides of the modular back panel through the fixing section, and is respectively fixed on the top panel and the main panel through the upper connecting section and the lower connecting section.

The advantage of this invention is that, by fixing one of the plate sides of the modular back panel through the side bracket, clamping another one of the plate sides through the bracket for reinforcing the structure of the backplate, and fixing the top end and the bottom end of the bracket for reinforcing the structure of the backplate on the top panel and the main panel of the power supply respectively, the modular back panel can be stably positioned on the installation panel of the power supply. The bracket for reinforcing the structure of the backplate is a thin and elongated sheet, so the bracket for reinforcing the structure of the backplate can provide additional support in a limited space to enhance the positioning of the modular back panel in all directions. Therefore, when the modular back panel is subjected to an external force upon plugging or unplugging, the modular back panel has a sufficient and even support force to prevent the modular back panel from shaking, tilting, or deviating, thereby avoiding problems such as solder cracking or damage to electronic components due to forced bending of the modular back panel.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a bracket for reinforcing the structure of the backplate in accordance with the present invention;

FIG. 2 is another perspective view of the bracket for reinforcing the structure of the backplate in FIG. 1;

FIG. 3 is a front view of the bracket for reinforcing the structure of the backplate in FIG. 1;

FIG. 4 is an enlarged view of the bracket for reinforcing the structure of the backplate installed on a power supply;

FIG. 5 is another enlarged view of the bracket for reinforcing the structure of the backplate installed on the power supply in FIG. 4;

FIG. 6 is an enlarged front view of the bracket for reinforcing the structure of the backplate installed on the power supply in FIG. 4;

FIG. 7 is an enlarged top view of the bracket for reinforcing the structure of the backplate installed on the power supply in FIG. 4;

FIG. 8 is another enlarged top view of the bracket for reinforcing the structure of the backplate installed on the power supply in FIG. 4;

FIG. 9 is a perspective view of a power supply in accordance with the present invention;

FIG. 10 is an enlarged view of a power supply in accordance with the prior art; and

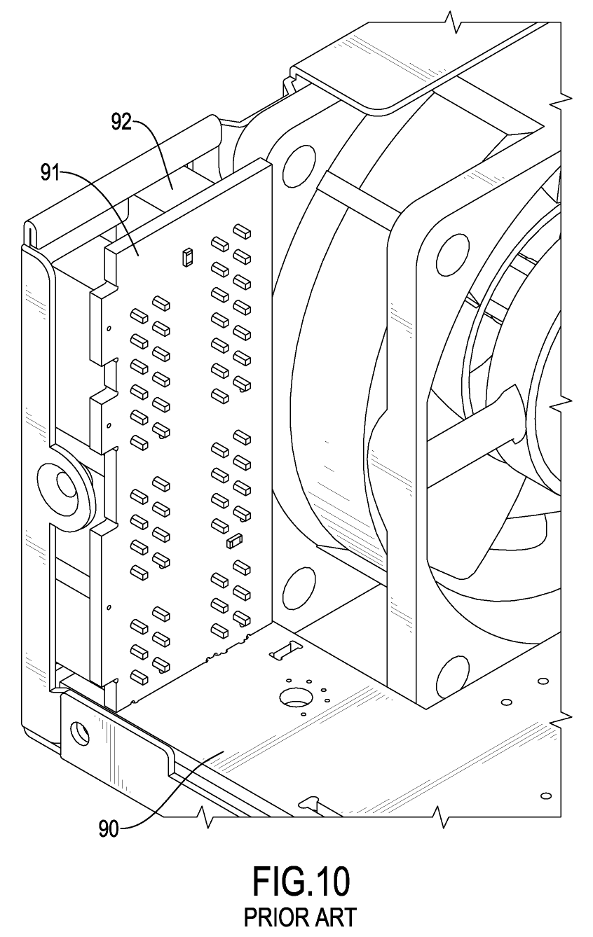

FIG. 11 is a top view of the power supply in FIG. 10.

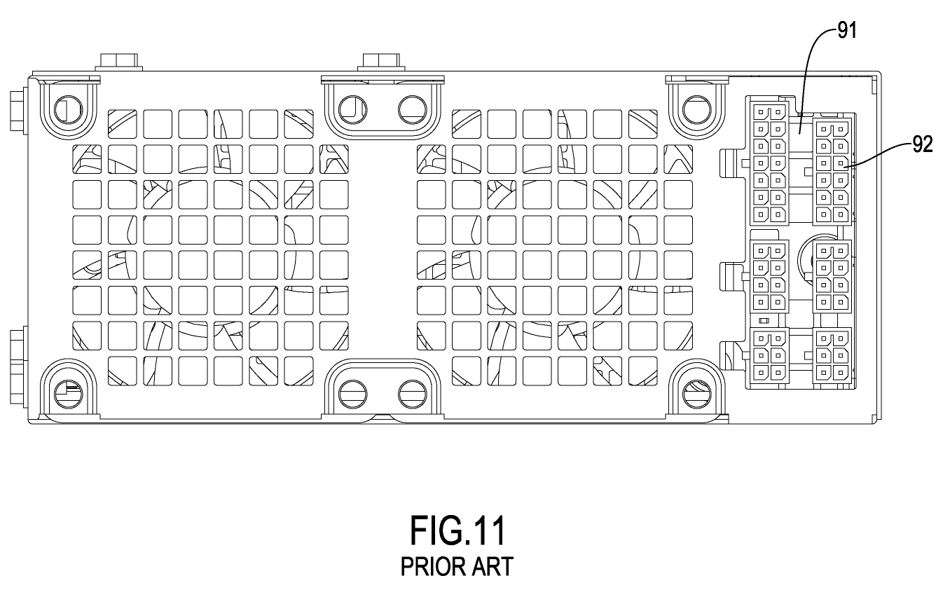

### DETAILED DESCRIPTION OF THE PREFERRED EMBODIMENTS

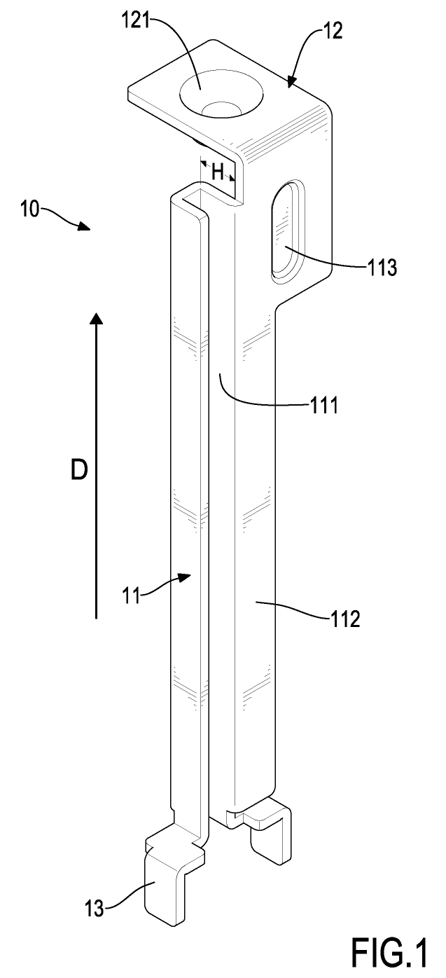

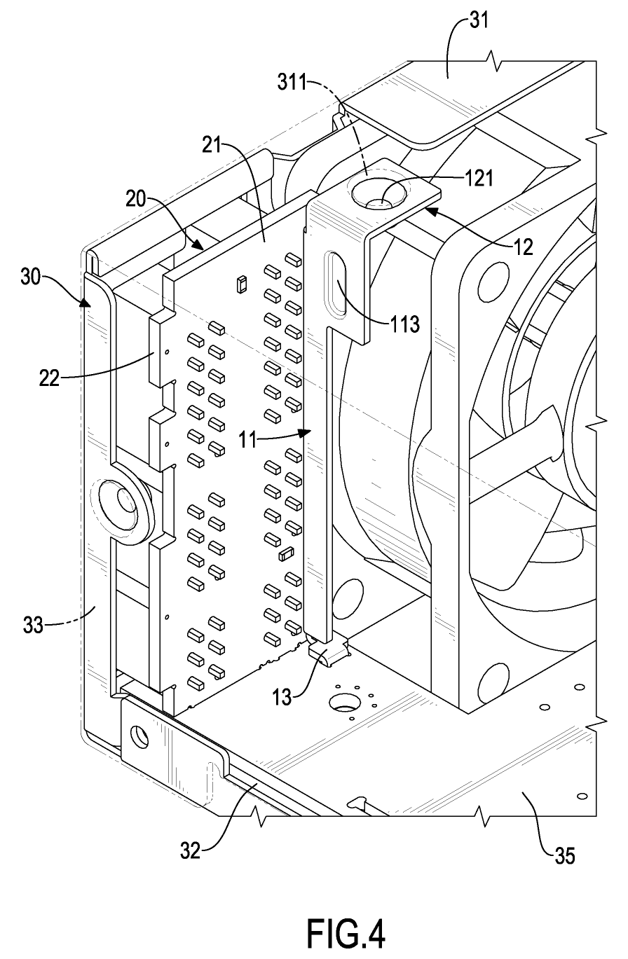

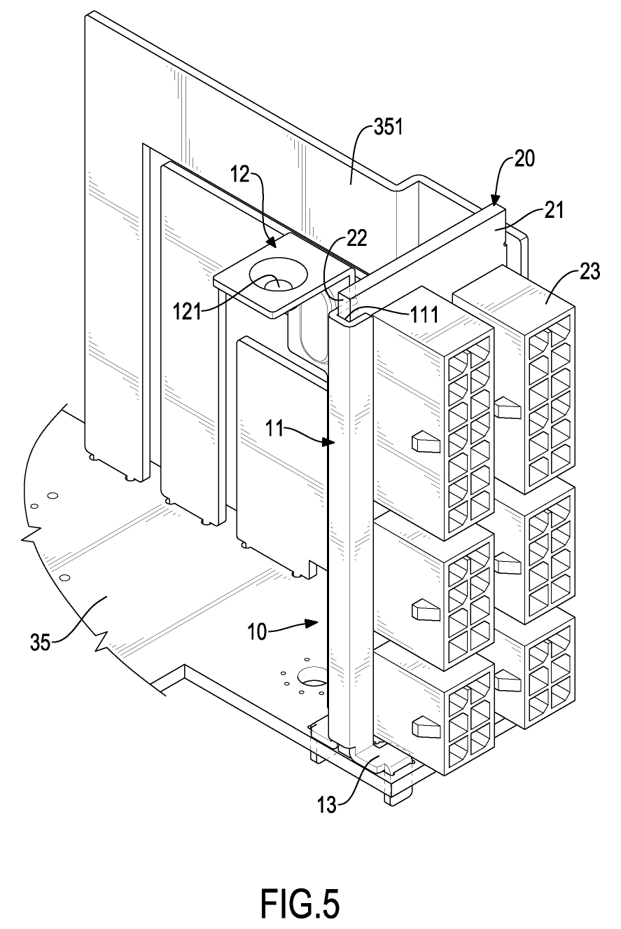

With reference to FIGS. 1 and FIG. 4, a bracket for reinforcing a structure of a backplate 10 in accordance with the present invention is configured to fix a modular back panel 20. The modular back panel 20 is a conventional printed circuit board and comprises two opposite plate surfaces 21 in front and back and two opposite plate sides 22 on left and right. With reference to FIG. 5, one of the plate surfaces 21 comprises at least one socket 23, which is a standard component of the prior art, and its structure will not be described in detail.

The bracket for reinforcing the structure of the backplate 10 is an elongated strip and includes a fixing section 11, an upper connecting section 12, and a lower connecting section 13. In this embodiment, the bracket for reinforcing the structure of the backplate 10 is a one-piece elongated strip.

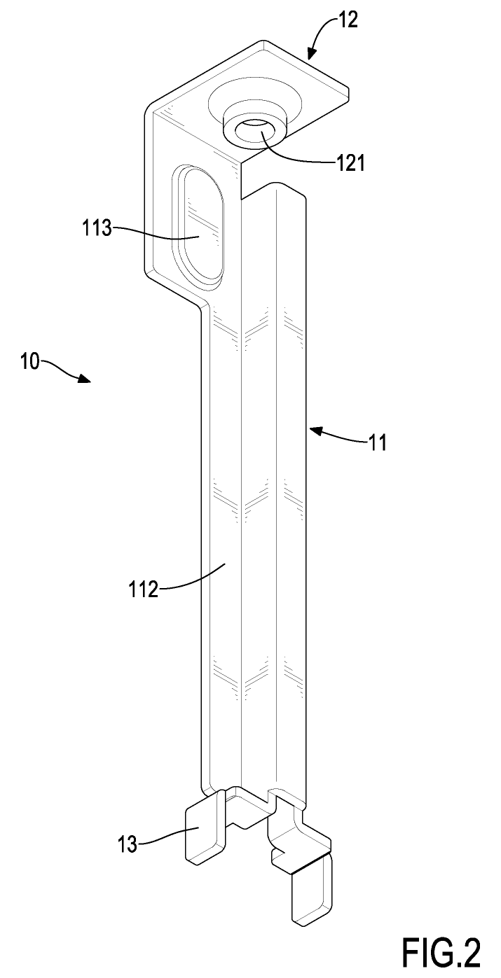

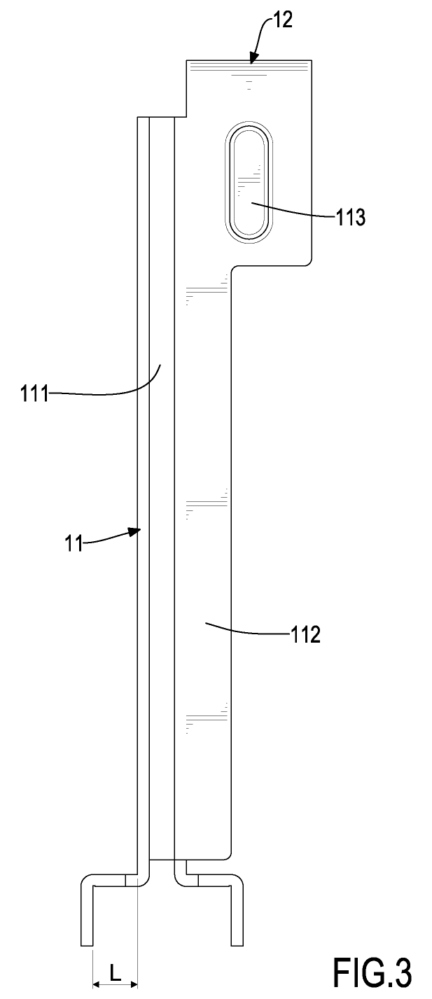

With reference to FIGS. 1 to FIG. 4, a fixing groove 111 is recessed laterally on the fixing section 11. In this embodiment, the fixing section 11 is an elongated rod with a U-shaped cross-section, such that the fixing groove 111 is a rectangular groove. A shape of the fixing groove 111 corresponds to a contour formed by one of the plate sides 22 and the two plate surfaces 21 connected to said one of the plate sides 22 of the modular back panel 20. In this embodiment, the fixing groove 111 has a wall height H, which is a height from an opening of the fixing groove 111 to a bottom of the fixing groove 111 and is least 2 mm. A reinforcing plate 112 extends laterally from the opening of the fixing groove 111 of the fixing section 11. The reinforcing plate 112 extends along an axial direction D of the fixing section 11 to form an elongated plate. A ridge part 113 is formed on an end of the reinforcing plate 112. The ridge part 113 defines a concave portion on a surface of the reinforcing plate 112 and a corresponding protruding portion on an opposite surface thereof, but it is not limited thereto. The fixing section 11 may not have the reinforcing plate 112 or the ridge part 113, and the configuration of the fixing section 11 can be changed according to the user's needs.

The upper connecting section 12 extends and bends from an end of the fixing section 11. An upper through hole 121 is formed through the upper connecting section 12.

With reference to FIGS. 1 to FIG. 5, the lower connecting section 13 bends from another end of the fixing section 11, extends for a distance, and then extends in a direction away from the fixing section 11. In this embodiment, the lower connecting section 13 includes two bent sheets. The two bent sheets respectively extend in two opposite directions to form an extending length L, and the extending length L is at least 0.8 mm. Then said two bent sheets bend and extend in a same direction, but it is not limited thereto. The configuration of the lower connecting section 13 can be changed according to the user's needs. For example, the lower connecting section 13 may include only one bent sheet or multiple bent sheets.

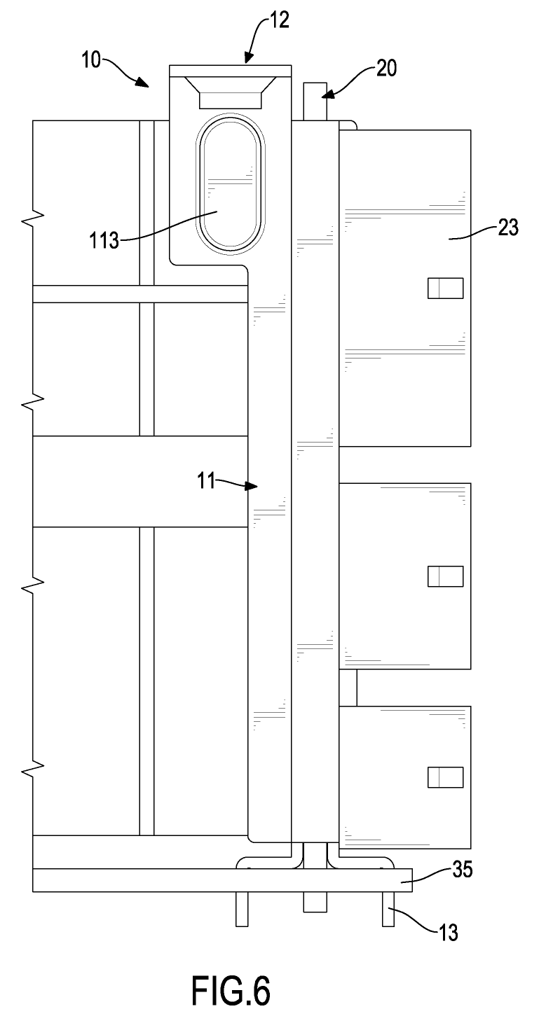

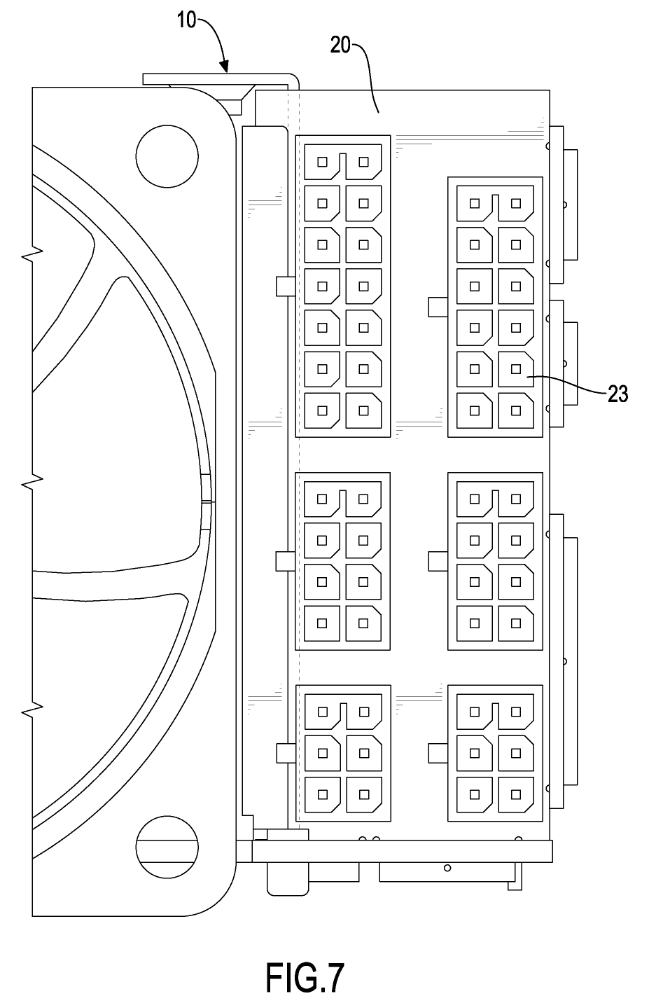

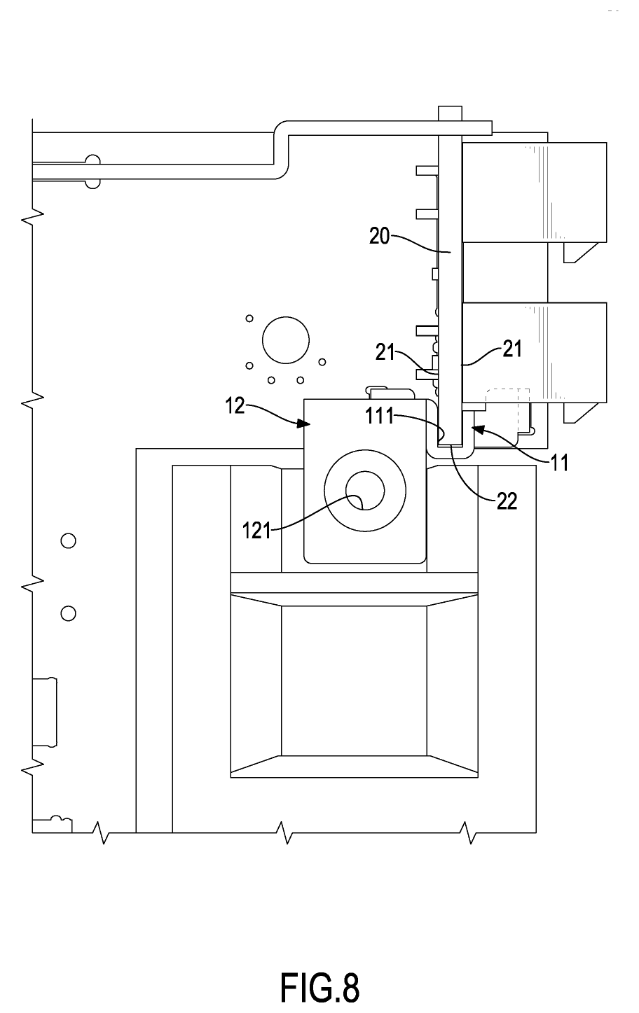

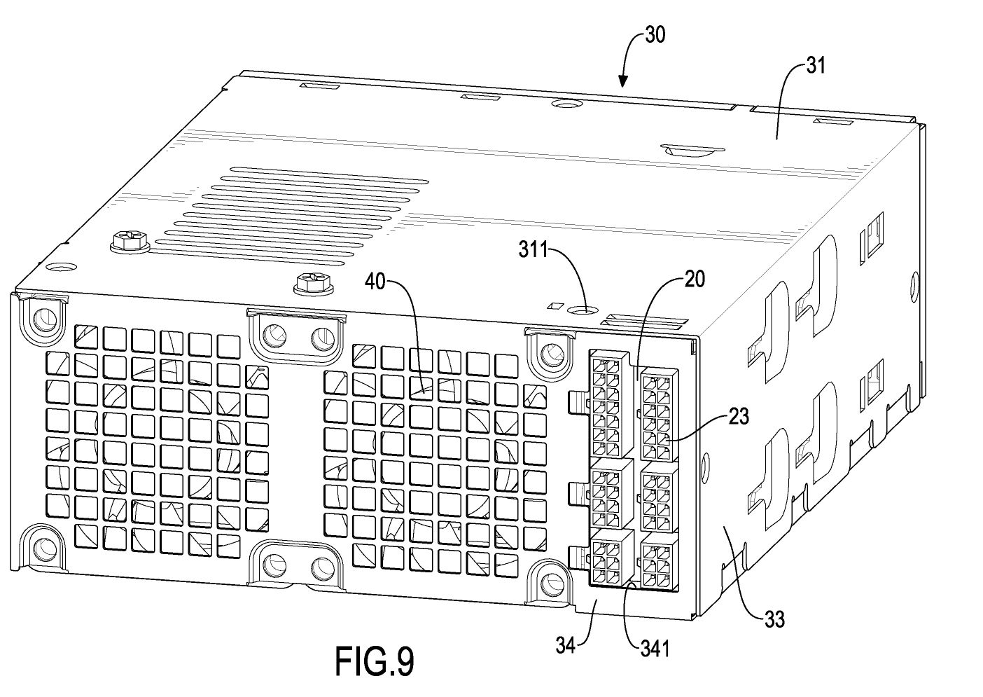

With reference to FIGS. 4 to FIG. 9, for use of the present invention, taking the modular back panel 20 installed on a casing assembly 30 as an example, the casing assembly 30 is illustrated as, but not limited to, a casing of a power supply. The casing assembly 30 comprises a top panel 31, a bottom panel 32, two side panels 33, an installation panel 34, and a rear plate (not shown in Fig.) to form an accommodating space with at least one connecting port 341. The rear plate is not the focus in the present invention, so the structure of the rear plate will not be described in detail. Instead, the top panel 31, one of the side panels 33, the bottom panel 32, and the installation panel 34 of the casing assembly 30 used in the present invention will be described.

The installation panel 34 is connected to the top panel 31 and the bottom panel 32. The side panel 33 is connected to the installation panel 34, the top panel 31, and the bottom panel 32 simultaneously. The installation panel 34 is an elongated and narrow rectangular plate with multiple air outlets for the fan to blow out air. The connecting ports 341 are located between each one of the air outlets and the side panel 33, indicating that a space around the connecting ports 341 is very limited. The top panel 31 of the casing assembly 30 comprises an apical hole 311. A main panel 35 is mounted on the bottom panel 32 and is parallel to the bottom panel 32. The modular back panel 20 is inserted into the main panel 35, and multiple sockets 23 are disposed on one of the side panels 33 of the modular back panel 20 facing the installation panel 34. Each one of the sockets 23 is mounted through a respective one of the connecting ports 341. At least one side bracket 351 protrudes from the main panel 35, and in this embodiment, there are multiple side brackets 351. The side brackets 351 are respectively connected to the main panel 35 and the plate side 22 of the modular back panel 20 close to the side panel 33, but it is not limited thereto. In other embodiments, the side brackets 351 may be omitted, and the side panel 33 of the casing assembly 30 may directly abut against or be connected to the modular back panel 20. The bracket for reinforcing the structure of the backplate 10 is sleeved on another plate side 22 of the modular back panel 20 through the opening of the fixing groove 111. Therefore, an inner edge of the fixing groove 111 abuts against the two plate surfaces 21 and said plate side 22 of the modular back panel 20. A fixing unit (not shown in Fig.) is mounted through the apical hole 311 and the upper through hole 121 and fixed, thereby fixing one end of the bracket for reinforcing the structure of the backplate 10 on the top panel 31 of the casing assembly 30, and another end of the bracket for reinforcing the structure of the backplate 10 is disposed through and secured to the main panel 35 with the lower connecting section 13.

In the aforementioned process, since one of the plate sides 22 of the modular back panel 20 is fixed through the side brackets 351, and the other one of the plate sides 22 and the two plate surfaces 21 are clamped by the bracket for reinforcing the structure of the backplate 10, the modular back panel 20 can be stably located on the installation panel 34 and the main panel 35 of the casing assembly 30. The bracket for reinforcing the structure of the backplate 10 is a thin and elongated sheet, so the bracket for reinforcing the structure of the backplate 10 can provide additional support in a limited space (the space between the fan and the modular back panel 20 in this embodiment) to enhance the positioning of the modular back panel 20 in all directions. Therefore, when a plug (not shown in Fig.) is plugged or unplugged and the modular back panel 20 is subjected to an external force, the modular back panel 20 has a sufficient and even support force to prevent the modular back panel 20 from shaking, tilting, or deviating, thereby avoiding problems such as solder cracking or damage to electronic components due to forced bending of the modular back panel 20.

In the aforementioned process, since the lower connecting section 13 of the bracket for reinforcing the structure of the backplate 10 is disposed through and secured to the main panel 35, the lower connecting section 13 can be installed and fixed in the solder pot at the same time as the main panel 35, which can reduce the process steps and costs.

In the aforementioned process, the reinforcing plate 112 and the ridge part 113 formed on the reinforcing plate 112 help to enhance the structural strength of the bracket for reinforcing the structure of the backplate 10.

In the aforementioned process, the number of the bracket for reinforcing the structure of the backplate 10 is not limited to one, but can also be two, and each one of the brackets for reinforcing the structure of the backplate can be sleeved on the two plate sides 22 of the modular back panel 20 through the fixing section 11.

Please refer to FIGS. 4, FIG. 5, and FIG. 9, which are perspective views of the power supply according to the embodiment of the present invention. The power supply comprises a casing assembly 30, a fan module 40, a main panel 35, and a modular back panel 20. The fan module 40 is mounted in the accommodating space of the casing assembly 30 and comprises an outlet side toward the installation panel 34.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A bracket for reinforcing a structure of a backplate configured to fix a modular back panel; the modular back panel comprising two opposite plate surfaces in front and back and two opposite plate sides on left and right; the bracket for reinforcing the structure of the backplate comprising:
a fixing section configured to cover one of the plate sides of the modular back panel;
an upper connecting section extending and bending from an end of the fixing section; an upper through hole formed through the upper connecting section; and
a lower connecting section bending from another end of the fixing section, extending for a distance, and then extending in a direction away from the fixing section.

2. The bracket for reinforcing the structure of the backplate as claimed in claim 1, wherein a fixing groove is recessed laterally on the fixing section; the fixing groove extending toward the two ends of the fixing section, and one of the plate sides located in the fixing groove.

3. The bracket for reinforcing the structure of the backplate as claimed in claim 2, wherein the fixing groove is a rectangular groove; a shape of the fixing groove corresponds to a contour formed by one of the plate sides and the two plate surfaces connected to said one of the plate sides of the modular back panel.

4. The bracket for reinforcing the structure of the backplate as claimed in claim 3, wherein a wall height of the fixing groove is at least 2 millimeters (mm).

5. The bracket for reinforcing the structure of the backplate as claimed in claim 2, wherein a reinforcing plate extends laterally from an opening of the fixing groove, and the reinforcing plate extends along an axial direction of the fixing section to form an elongated plate.

6. The bracket for reinforcing the structure of the backplate as claimed in claim 4, wherein a reinforcing plate extends laterally from an opening of the fixing groove, and the reinforcing plate extends along an axial direction of the fixing section to form an elongated plate.

7. The bracket for reinforcing the structure of the backplate as claimed in claim 5, wherein a ridge part is formed on an end of the reinforcing plate; the ridge part is concave on a surface of the reinforcing plate and protrudes from another surface of the reinforcing plate.

8. The bracket for reinforcing the structure of the backplate as claimed in claim 6, wherein a ridge part is formed on an end of the reinforcing plate; the ridge part is concave on a surface of the reinforcing plate and protrudes from another surface of the reinforcing plate.

9. The bracket for reinforcing the structure of the backplate as claimed in claim 1, wherein the lower connecting section includes two bent sheets; the two bent sheets respectively extend in two opposite directions and then bend and extend in a same direction.

10. The bracket for reinforcing the structure of the backplate as claimed in claim 8, wherein the lower connecting section includes two bent sheets; the two bent sheets respectively extend in two opposite directions and then bend and extend in a same direction.

11. The bracket for reinforcing the structure of the backplate as claimed in claim 9, wherein the bent sheets of the lower connecting section extend in opposite directions to respectively define extending lengths; the extending length is at least 0.8 mm.

12. The bracket for reinforcing the structure of the backplate as claimed in claim 10, wherein the bent sheets of the lower connecting section extend in opposite directions to respectively define extending lengths; the extending length is at least 0.8 mm.

13. A power supply comprising:
a casing assembly comprising a top panel, a side panel, a bottom panel, and an installation panel to form an accommodating space with at least one connecting port; the installation panel connected to the top panel and the bottom panel; the side panel connected to the installation panel, the top panel, and the bottom panel;
a fan module mounted in the accommodating space and comprising an outlet side toward the installation panel;
a main panel mounted on the bottom panel; and
a modular back panel mounted on the main panel and comprising two opposite plate surfaces in front and back and two opposite plate sides on left and right;
wherein the casing assembly further comprises:
a bracket for reinforcing a structure of a backplate fixing the modular back panel, and the bracket comprising:
a fixing section configured to cover one of the plate sides of the modular back panel;
an upper connecting section extending and bending from an end of the fixing section; an upper through hole formed through the upper connecting section; and
a lower connecting section bending from another end of the fixing section, extending for a distance, and then extending in a direction away from the fixing section.

14. The power supply as claimed in claim 13, wherein at least one side bracket is mounted on the main panel; an end of the at least one side bracket connected to the main panel, and another end of the at least one side bracket connected to the other one of the two plate sides of the modular back panel.

15. The power supply as claimed in claim 13, wherein the top panel comprises an apical hole; the upper connecting section mounted through the apical hole and the upper through hole via a fixing unit to be fixed on the top panel; the lower connecting section disposed through and secured to the main panel.
